(19) United States
(12) Patent Application Publication
(10) Pub. No.: US 2014/0174911 A1
(43) Pub. Date: Jun. 26, 2014

(54) Methods and Systems for Reducing Particles During Physical Vapor Deposition

(71) Applicant: INTERMOLECULAR, INC., San Jose, CA (US)

(72) Inventor: Chi-I Lang, Cupertino, CA (US)

(73) Assignee: INTERMOLECULAR, INC., San Jose, CA (US)

(21) Appl. No.: 13/725,846

(22) Filed: Dec. 21, 2012

(51) Int. Cl. C23C 14/35; H01L 21/02

(52) U.S. Cl. CPC C23C 14/35; H01L 21/0226
USPC 204/192.12; 204/298.12; 204/298.13; 438/758

(57) ABSTRACT

Embodiments provided herein describe methods and systems for depositing material onto a surface. A target including a material in a porous state is provided. The density of the material in the porous state is less than 89% of the absolute density of the material. The target is positioned over a surface. At least some of the material is caused to be ejected from the target and deposited onto the surface.

The present invention relates to physical vapor deposition (PVD). More particularly, this invention relates to methods and systems for reducing particles deposited from targets during PVD.

### BACKGROUND OF THE INVENTION

Physical vapor deposition (PVD) is a commonly used technique for depositing material in, for example, semiconductor, solar, and window panel operations. Generally, it is desirable to deposit the material in a consistent, uniform manner. Typically, the material is deposited by being ejected from targets that are manufactured in a manner as to make the targets as dense as possible in order to maximize the amount of material that may be deposited from a single target and to maximize the conductivity and mechanically strength of the targets.

However, when conventional, high density materials are used, the targets often experience significant spalling and cracking, particularly when relatively brittle materials are used, such as a tantalum-silicon alloy. As a result, the material is often deposited in an uneven, inconsistent manner, as large particles (i.e., chunks) unpredictably break off and are ejected from the target.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration that includes site isolated processing and/or conventional processing in accordance with some embodiments of the present invention.

FIG. 3 is a simplified schematic diagram illustrating an integrated high productivity combinatorial (HPC) system in accordance with some embodiments of the present invention.

FIG. 4 is a simplified schematic diagram illustrating a sputter processing chamber configured to perform combinatorial processing and full substrate processing in accordance with some embodiments of the present invention.

FIG. 5 is a simplified schematic diagram illustrating a sputter processing gun configured to perform combinatorial processing and full substrate processing before implementation of some embodiments of the present invention.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

Embodiments of the present invention provide for the use of relatively low density and/or high porosity targets for physical vapor deposition (PVD) of brittle materials. Conventional wisdom suggests manufacturing PVD targets with high density and/or low porosity, as it maximizes the amount of material that may be deposited from a single target, and it maximizes the conductivity and mechanical strength of the targets. However, in use, conventional, high density targets often exhibit considerable spalling and cracking, particularly when the targets are made of brittle materials.

Brittle materials (or compounds) are, for example, those that break without a significant amount of deformation or strain (e.g., substantially no deformation or strain) when subjected to stress and/or absorb relatively little energy prior to fracture, even if the material is high strength. Generally, examples of brittle materials include ceramics, various types of glass, and some polymers, such as polymethyl methacrylate (PMMA) and polystyrene.

One particular type of brittle material sometimes utilized in PVD targets is tantalum-silicon alloys. When used in PVD targets, the brittle material is often ejected from the in an inconsistent manner, as large particles (i.e., chunks of the target material) sporadically break loose, resulting in defects in the deposited layer or material.

In accordance with some embodiments of the present invention, by intentionally manufacturing PVD targets made of materials (and/or compounds) with low density and/or high porosity, particularly when brittle materials are used, potential spalling and cracking may be reduced, thus resulting in less defects during the deposition of the material. In some embodiments, the target(s) used includes a material in a porous state. The density of the material in the porous state is less than 89% of the absolute density (i.e., non-porous density) of the material.

Additionally, embodiments described herein provide methods and systems for developing and evaluating materials and processing conditions. In some embodiments, a plurality of regions (e.g., site-isolated regions) are designated on at least one substrate (e.g., a semiconductor or glass substrate). A first material is formed on a first of the plurality of regions on the at least one substrate with a first set of processing conditions. A second material is formed on a second of the plurality of regions on the at least one substrate with a second set of processing conditions. The second set of processing conditions is different than the first set of processing conditions. The first material and the second material may then be characterized. One of the first set of processing conditions and the second set of processing conditions may be selected based on the characterizing of the first material and the second material.

As such, in accordance with some embodiments, combinatorial processing may be used to produce and evaluate different materials, chemicals, processes, as well as build structures or determine how materials coat, fill or interact with existing structures in order to vary materials, unit processes and/or process sequences across multiple site-isolated regions on the substrate(s). These variations may relate to specifications such as temperatures, exposure times, layer thicknesses, chemical compositions, humidity, etc. of the formulations and/or the substrates at various stages of the screening processes described herein. However, it should be noted that in some embodiments, the chemical composition remains the same, while other parameters are varied, and in other embodiments, the chemical composition is varied.

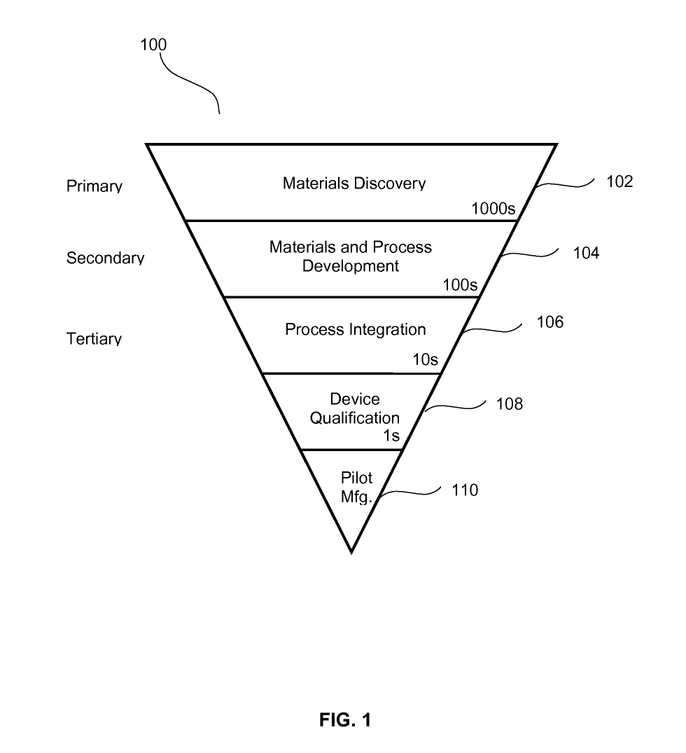

FIG. 1 illustrates a schematic diagram 100 for implementing combinatorial processing and evaluation using primary, secondary, and tertiary screening. The schematic diagram 100 illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage 102. Materials discovery stage 102 is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage 104. Evaluation of the materials is performed using metrology tools such as electronic testers and imaging tools (i.e., microscopes).

The materials and process development stage 104 may evaluate hundreds of materials (i.e., a magnitude smaller than the primary stage) and may focus on the processes used to deposit or develop those materials. Promising materials and processes are again selected, and advanced to the tertiary screen or process integration stage 106 where tens of materials and/or processes and combinations are evaluated. The tertiary screen or process integration stage 106 may focus on integrating the selected processes and materials with other processes and materials.

The most promising materials and processes from the tertiary screen are advanced to device qualification 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing 110.

The schematic diagram 100 is an example of various techniques that may be used to evaluate and select materials and processes for the development of new materials and processes. The descriptions of primary, secondary, etc. screening and the various stages 102-110 are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007, which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of thermochromic devices, semiconductor devices, TFPV modules, optoelectronic devices, etc. manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating semiconductor devices, TFPV modules, optoelectronic devices, thermochromic devices, etc. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture semiconductor devices, TFPV modules, optoelectronic devices, thermochromic devices, etc. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor devices, TFPV modules, optoelectronic devices, thermochromic devices, etc. For example, such structures may include, but would not be limited to, contact layers, buffer layers, absorber layers, or any other series of layers or unit processes that create an intermediate structure found on semiconductor devices, TFPV modules, optoelectronic devices, thermochromic devices, etc. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different designated regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete (or site-isolated) regions on the substrate can be defined as needed, but are preferably systematized for ease of tooling and design of experimentation. In addition, the number, variants and location of structures within each region are designed to enable valid statistical analysis of the test results within each region and across regions to be performed.

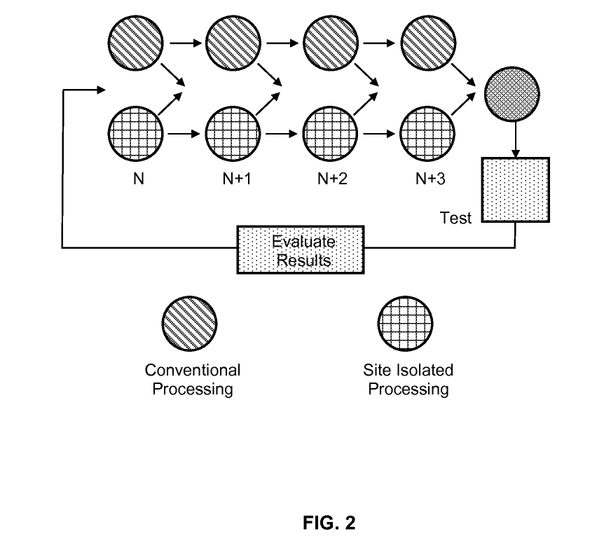

FIG. 2 is a simplified schematic diagram illustrating a general methodology for combinatorial process sequence integration that includes site isolated processing and/or conventional processing in accordance with some embodiments of the invention. In some embodiments, the substrate is initially processed using conventional process N. In some exemplary embodiments, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor device, TFPV module, optoelectronic device, etc. manufacturing may be varied.

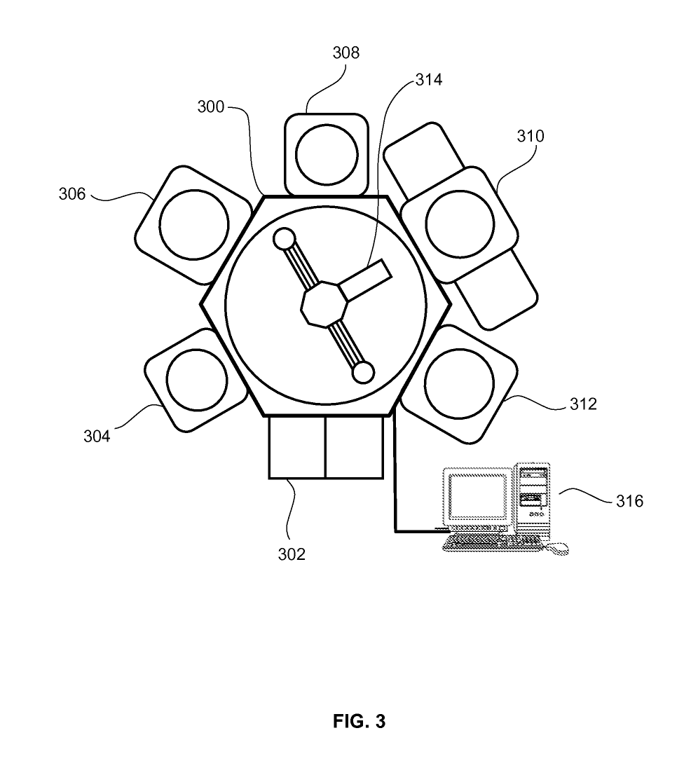

FIG. 3 is a simplified schematic diagram illustrating an integrated high productivity combinatorial (HPC) system in accordance with some embodiments of the invention. HPC system includes a frame 300 supporting a plurality of processing modules. It should be appreciated that frame 300 may be a unitary frame in accordance with some embodiments. In some embodiments, the environment within frame 300 is controlled. Load lock/factory interface 302 provides access into the plurality of modules of the HPC system. Robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system, including the power supplies and synchronization of the duty cycles described in more detail below. Further details of one possible HPC system are described in U.S. application Ser. No. 11/672,478 filed Feb. 7, 2007, now U.S. Pat. No. 7,867,904 and claiming priority to U.S. Provisional Application No. 60/832,248 filed on Jul. 19, 2006, and U.S. application Ser. No. 11/672,473, filed Feb. 7, 2007, and claiming priority to U.S. Provisional Application No. 60/832,248 filed on Jul. 19, 2006, which are all herein incorporated by reference. With HPC system, a plurality of methods may be employed to deposit material upon a substrate employing combinatorial processes.

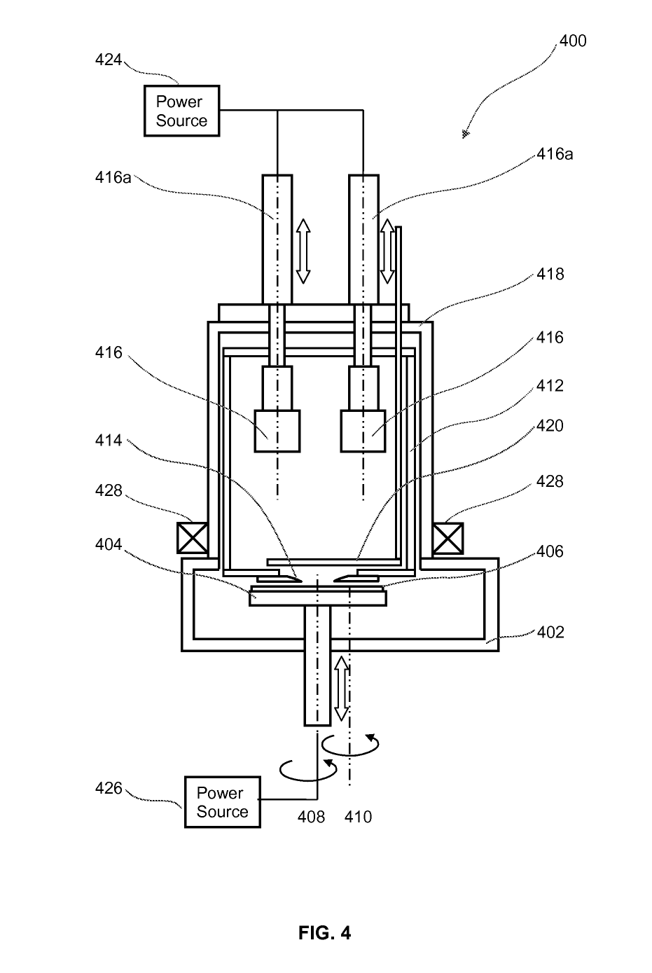

FIG. 4 is a simplified schematic diagram illustrating a PVD chamber, more particularly, a sputter chamber, configured to perform combinatorial processing and full substrate processing in accordance with some embodiments of the invention. Processing chamber (or processing tool) 400, includes (and is defined by) a bottom chamber portion 402 disposed under top chamber portion 418. Within bottom portion 402 substrate support 404 is configured to hold a substrate 406 disposed thereon and can be any known substrate support, including but not limited to a vacuum chuck, electrostatic chuck or other known mechanisms. Substrate support 404 is capable of both rotating around its own central axis, 408 (referred to as “rotation” axis), and rotating around an exterior axis 410 (referred to as “revolution” axis). Such dual rotary substrate support is central to combinatorial processing using site-isolated mechanisms. Other substrate supports, such as an XY table, can also be used for site-isolated deposition. In addition, substrate support, 404, may move in a vertical direction. It should be appreciated that the rotation and movement in the vertical direction may be achieved through known drive mechanisms which include magnetic drives, linear drives, worm screws, lead screws, a differentially pumped rotary feed through drive, etc. Power source 426 provides a bias power to substrate support, 404, and substrate 406 and produces a negative bias voltage on substrate 406. In some embodiments power source 426 provides a radio frequency (RF) power sufficient to take advantage of the high metal ionization to improve step coverage of vias and trenches of patterned wafers. In some embodiments, the RF power supplied by power source 426 is pulsed and synchronized with the pulsed power from power source 424.

Substrate 406 may be a conventional round 200 mm, 300 mm, or any other larger or smaller substrate/wafer size. In some embodiments, substrate 406 may be a square, rectangular, or other shaped substrate. In some embodiments, substrate 406 is made of glass. However, in other embodiments, the substrate 406 is made of a semiconductor material, such as silicon. One skilled in the art will appreciate that substrate 406 may be a blanket substrate, a coupon (e.g., partial wafer), or even a patterned substrate having predefined regions. In some embodiments, substrate 406 may have regions defined through the processing described herein. The term region is used herein to refer to a localized (or site-isolated) area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field, a region may be, for example, a test structure, single die, multiple dies, portion of a die, other defined portion of substrate, or an undefined area of a substrate, e.g., blanket substrate which is defined through the processing.

Top chamber portion 418 of chamber 400 in FIG. 4 includes process kit shield 412 which defines a confinement region over a radial portion of substrate, 406. Process kit shield 412 is a sleeve having a base (optionally integrated with the shield) and an optional top within chamber 400 that may be used to confine a plasma generated therein. The generated plasma will dislodge atoms from a target and the sputtered atoms will deposit on an exposed surface of substrate 406 to combinatorial process regions of the substrate in a site-isolated manner (e.g., such that only the particular region on the substrate is processed) in some embodiments. In other embodiments, full wafer processing can be achieved by optimizing gun tilt angle and target-to-substrate spacing, and by using multiple process guns 416. Process kit shield 412 is capable of being moved in and out of chamber 400 (i.e., the process kit shield is a replaceable insert). In other embodiments, process kit shield 412 remains in the chamber for both the full substrate and combinatorial processing. Process kit shield 412 includes an optional top portion, sidewalls and a base. In some embodiments, process kit shield 412 is configured in a cylindrical shape, however, the process kit shield may be any suitable shape and is not limited to a cylindrical shape.

The base of process kit shield 412 includes an aperture 414 through which a surface of substrate 406 is exposed for deposition or some other suitable semiconductor processing operations. Aperture shutter 420 which is moveably disposed over the base of process kit shield 412. Aperture shutter 420 may slide across a bottom surface of the base of process kit shield 412 in order to cover or expose aperture 414 in some embodiments. In other embodiments, aperture shutter 420 is controlled through an arm extension which moves the aperture shutter to expose or cover aperture 414. It should be noted that although a single aperture is illustrated, multiple apertures may be included. Each aperture may be associated with a dedicated aperture shutter or an aperture shutter can be configured to cover more than one aperture simultaneously or separately. Alternatively, aperture 414 may be a larger opening and aperture shutter 420 may extend with that opening to either completely cover the aperture or place one or more fixed apertures within that opening for processing the defined regions. The dual rotary substrate support 404 is central to the site-isolated mechanism, and allows any location of the substrate or wafer to be placed under the aperture 414. Hence, the site-isolated deposition is possible at any location on the wafer/substrate.

In the example shown in FIG. 4, two process guns 416 are included. Process guns 416 are moveable in a vertical direction so that one or both of the guns may be lifted from the slots of the shield. While two process guns are illustrated, any number of process guns may be included, e.g., one, three, four or more process guns may be included. Where more than one process gun is included, the plurality of process guns may be referred to as a cluster of process guns. In some embodiments, process guns 416 are oriented or angled so that a normal reference line extending from a planar surface of the target of the process gun is directed toward an outer periphery of the substrate in order to achieve good uniformity for full substrate deposition film. The target/gun tilt angle depends on the target size, target-to-substrate spacing, target material, process power/pressure, etc.

Top chamber portion 418 of chamber 400 of FIG. 4 includes sidewalls and a top plate which house process kit shield 412. Arm extensions, 416a, which are fixed to process guns 416 may be attached to a suitable drive, (i.e., lead screw, worm gear, etc.), configured to vertically move process guns 416 toward or away from a top plate of top chamber portion 418. Arm extensions 416a may be pivotally affixed to process guns, 418 to enable the process guns to tilt relative to a vertical axis. In some embodiments, process guns 416 tilt toward aperture 414 when performing combinatorial processing and tilt toward a periphery of the substrate being processed when performing full substrate processing. It should be appreciated that process guns 416 may tilt away from aperture 414 when performing combinatorial processing in other embodiments. In yet other embodiments, arm extensions 416a are attached to a bellows that allows for the vertical movement and tilting of process guns 416. Arm extensions 416a enable movement with four degrees of freedom in some embodiments. Where process kit shield 412 is utilized, the aperture openings are configured to accommodate the tilting of the process guns. The amount of tilting of the process guns may be dependent on the process being performed in some embodiments.

Power source 424 provides power for sputter guns 416 whereas power source 426 provides RF bias power to an electrostatic chuck. As mentioned above, the output of power source 426 is synchronized with the output of power source 424. It should be appreciated that power source 424 may output a direct current (DC) power supply or a radio frequency (RF) power supply. In other embodiments, the DC power is pulsed and the duty cycle is less than 30% on-time at maximum power in order to achieve a peak power of 10-15 kilowatts. Thus, the peak power for high metal ionization and high density plasma is achieved at a relatively low average power which will not cause any target overheating/cracking issues. It should be appreciated that the duty cycle and peak power levels are exemplary and not meant to be limiting as other ranges are possible and may be dependent on the material and/or process being performed.

Chamber 400 also includes magnet 428 disposed around an external periphery of the chamber. Magnet 428 is located in a region defined between the bottom surface of sputter guns 416 and a top surface of substrate 406. Magnet 428 may be either a permanent magnet or an electromagnet. It should be appreciated that magnet 428 is utilized to improve ion guidance as the magnetic field distribution above substrate 406 is re-distributed or optimized to guide metal ions on to the substrate for improved step coverage of vias or trenches in semiconductor devices in some embodiments.

Although not shown in FIG. 4, the chamber 400 may also include a control system having, for example, a processor and a memory, which is in operable communication with the other components shown in FIG. 4 and configured to control the operation thereof in order to perform the methods described herein.

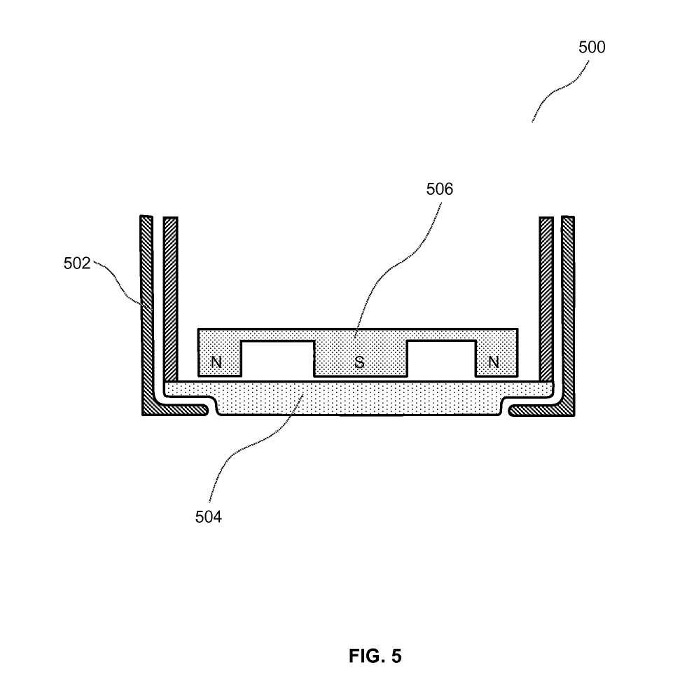

FIG. 5 is a simplified schematic diagram illustrating a sputter processing chamber configured to perform combinatorial processing and full substrate processing before implementation of some embodiments of the present invention. FIG. 5 illustrates a portion of a sputter gun 500 that would be part of the sputter gun 416 in FIG. 4. Illustrated in FIG. 5 is a grounded shield 502 surrounding the exterior of target 504 and magnetron assembly 506.

In accordance with some embodiments of the present invention, the target 504 includes a material in a porous state. That is, the material of the target 504 is not completely “solid,” but has small pockets of air therein. More specifically, in the porous state, the density of the material is less than the absolute density of the material. Absolute density may refer to a state of a material in which the material is completely solid and/or completely void of pores (i.e., non-porous).

In some embodiments, the density of the target material in the porous state is less than 89% (e.g., not more than 88%) of the density of the same material in the non-porous state. For example, in some embodiments, the target 504 is made of a tantalum-silicon alloy. In such embodiments, the tantalum-silicon is porous such that the density thereof is less than 89% of the absolute density of tantalum-silicon. In some embodiments, the density of the material in the porous state is between 50% and 89% of the absolute density of the material, such as 75% of the absolute density of the material.

In some embodiments, the target(s) 504 is manufactured using hot isostatic pressing (HIP). As will be appreciated by one skilled in the art, HIP is typically used to reduce the porosity (and/or increase the density) of the materials used for PVD targets. The process often involves subjecting the material (e.g., the target) to high temperatures and high isostatic gaseous pressure (e.g., using an inert gas, such as argon). In conventional HIP for PVD targets, the gaseous pressure applied is between 7350 and 15000 pounds per square inch (psi), while the temperature is raised to, for example, between 482° C. and 2400° C.

However, in some embodiments of the present invention, the target(s) 504 is manufactured using a non-conventional HIP process, in which the gaseous pressure and/or temperature is kept below that used in HIP processes used for manufacturing conventional PVD targets. As a result, the target(s) 504 retain a significant amount of porosity and the density thereof is lower than that of conventional PVD targets.

Due to the low density of the target(s), when material is caused to be ejected thereof from and onto a surface (e.g., of the substrate positioned below), the likelihood of spalling and cracking of the target may be reduced. That is, the manner in which material is ejected from the target(s) may be made consistent, as opposed to relatively large chunks or particles being broken off from the target(s). As a result, the number of defects in (or on) the material deposited may be reduced.

Table 1 describes the results of an experiment comparing PVD deposition using a conventional, high density target compared to one of the low density targets described herein. Both targets were made of a tantalum-silicon alloy, with the high density target being near absolute density (e.g., ˜99% of absolute density) and the low density target being approximately 88% of absolute density.

TABLE 1
Particle Count for High Density and Low Density Targets

| | Time (s) | Thx (Å) | Particle Count | PC/Å | PC/s |
|---|---|---|---|---|---|
| High Density | 120 | 80 | 1177 | 14.7 | 9.8 |
| Low Density | 120 | 75 | 493 | 6.6 | 4.1 |

As shown, material was ejected from both targets for 120 seconds (s). The material ejected from the high density target formed a layer 80 Å thick (Thx), while the material ejected from the low density target formed a layer 75 Å thick. Of particular interest is the comparison of the particle counts. During deposition using the high density target, 1177 large particles were ejected (thus, 1177 defects were formed in the deposited layer). Thus, the particle count per unit thickness (A) was 14.7, and the particle count per unit time (s) was 9.8. In contrast, during deposition using the low density target, 493 large particles were ejected (and 493 defects were formed in the deposited layer). Thus, the particle count per unit thickness (A) was 6.6, and the particle count per unit time (s) was 4.1. Overall, the results demonstrate that the use of the low density target resulted in a particle/defect count of less than 50% of that of the conventional, high density target.

In addition to the tantalum-silicon alloy, other materials that may be used in the target(s) 504 include, for example, tin, zinc, magnesium, aluminum, lanthanum, yttrium, titanium, antimony, strontium, bismuth, tantalum, silicon, silver, nickel, chromium, or any combination thereof (i.e., a single target may be made of an alloy of several metals). Additionally, the materials used in the targets may include oxygen, nitrogen, fluorides, silicides, carbides, borides, or a combination thereof in order to form oxides, nitrides, oxynitrides, etc.

During sputtering, inert gases, such as argon or krypton, may be introduced into the processing chamber 400. In embodiments in which reactive sputtering is used, reactive gases may also be introduced to which the material is exposed, such as oxygen and/or nitrogen, and which interact with particles ejected from the targets (i.e., to form oxides, nitrides, and/or oxynitrides).

Using processing chamber 400, perhaps in combination with other processing tools, materials may be developed and evaluated in the manner described above. In particular, in some embodiments, materials may be formed on different site-isolated regions of substrate 406 (or on multiple substrates) under varying processing conditions (including the formation/deposition of different thermochromic material). For example, material may be ejected from one of more of targets 504 and deposited onto a first of the regions on substrate 406 under a first set of processing conditions, and either sequentially or simultaneously, material may be ejected from one of more of targets 504 and deposited onto a second of the regions on substrate 406 under a different, second set of processing conditions. The material(s) (and/or processing conditions) may then be characterized. Particular materials and/or processing conditions may then be selected (e.g., for further testing or use in devices) based on the desired parameters.

Thus, in some embodiments, a method for depositing material onto a surface is provided. A target including a material in a porous state is provided. The density of the material in the porous state is less than 89% of the absolute density of the material. The target is positioned over a surface. At least some of the material is caused to be ejected from the target and deposited onto the surface.

In other embodiments, a method for depositing material onto a substrate is provided. A target including a material in a porous state is provided. The density of the material in the porous state is between 50% and 89% of the absolute density of the material. The target is positioned over a substrate. At least some of the material is caused to be ejected from the target and deposited onto the substrate.

In further embodiments, a substrate processing tool is provided. The substrate processing tool includes a housing having a sidewall and a lid. The housing defines a processing chamber. A substrate support is coupled to the housing and configured to support a substrate within the processing chamber. A target is coupled to the housing such that the target is exposed to the processing chamber. The target includes a material in a porous state. The density of the material in the porous state is less than 89% of the absolute density of the material. A power supply is coupled to the target and configured to provide direct current (DC) power to the target to cause the material to be ejected from the target and deposited onto the substrate.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for depositing a material, the method comprising:
providing a target,
wherein the target comprises a material in a porous state,
wherein a density of the material in the porous state is less than 89% of an absolute density of the material;
positioning the target over a surface; and
causing at least some of the material to be ejected from the target and deposited on the surface.

2. The method of claim 1, wherein the material comprises a brittle compound such that the material fractures with substantially no deformation when a stress is applied thereto.

3. The method of claim 2, wherein the material comprises a tantalum-silicon alloy.

4. The method of claim 1, wherein the density of the material in the porous state is greater than 50% of the absolute density of the material.

5. The method of claim 1, wherein the surface is a surface of a substrate.

6. The method of claim 5, wherein the substrate comprises a semiconductor material.

7. The method of claim 5, wherein the substrate comprises glass.

8. The method of claim 1, wherein the causing of the at least some of the material to be ejected from the target comprises providing direct current (DC) power to the target.

9. The method of claim 8, further comprising exposing the at least some of the material ejected from the target to a gas before the material is deposited onto the surface.

10. The method of claim 9, wherein the gas comprises oxygen, nitrogen, or a combination thereof.

11. A method for depositing material, the method comprising:
providing a target,
wherein the target comprises a material in a porous state,
wherein a density of the material in the porous state is between 50% and 89% of an absolute density of the material;
positioning the target over a substrate; and
causing at least some of the material to be ejected from the target and deposited on the substrate.

12. The method of claim 11, wherein the causing of the material to be ejected from the target comprises providing direct current (DC) power to the target.

13. The method of claim 12, wherein the material comprises a brittle compound such that the material fractures with substantially no deformation when a stress is applied thereto.

14. The method of claim 13, wherein the material comprises a tantalum-silicon alloy.

15. The method of claim 11, wherein the substrate comprises a semiconductor material.

16. A substrate processing tool comprising:
a housing comprising a sidewall and a lid, the housing defining a processing chamber;
a substrate support coupled to the housing and configured to support a substrate within the processing chamber;
a target coupled to the housing such that the target is exposed to the processing chamber,
wherein the target comprises a material in a porous state,
wherein a density of the material in the porous state is less than 89% of an absolute density of the material; and
a power supply coupled to the target and configured to provide direct current (DC) power to the target to cause the material to be ejected from the target and deposited on the substrate.

17. The substrate processing tool of claim 16, wherein the material comprises a brittle compound such that the material fractures with substantially no deformation when a stress is applied thereto.

18. The substrate processing tool of claim 17, wherein the material comprises a tantalum-silicon alloy.

19. The substrate processing tool of claim 18, wherein the substrate comprises a semiconductor material.

20. The substrate processing tool of claim 19, wherein the substrate comprises glass.
